(19) United States
(12) Patent Application Publication
(10) Pub. No.: US 2005/0161073 A1
(43) Pub. Date: Jul. 28, 2005

(54) Positioning system for portable solar panels

(76) Inventors: Ray Head, Poulsbo, WA (US); Cindy S. Head, Poulsbo, WA (US)

Correspondence Address: Carl G. Dowrey;DOWREY RICKARDS PLLC, Suite 106, 19119 North Creek Parkway, Bothell, WA, 98011, US

(21) Appl. No.: 11/026,205

(22) Filed: Dec. 30, 2004

Related U.S. Application Data
(60) Provisional application No. 60/538,834, filed on Jan. 23, 2004.

(51) Int. Cl. H01L 25/00; H02N 6/00

(52) U.S. Cl. 136/245

(57) ABSTRACT

A solar panel(s) positioning apparatus for controlling the orientation of a solar panel(s) having one edge pivotally mounted to a support surface including a lift bar attached to an opposite edge of the panel(s) and having a mast, a base supported on the support surface, a swing link connected between the base and the mast and an extensible ling pivotally connected between an intermediate point on the base end of the mast.

### CROSS REFERENCE TO RELATED APPLICATIONS

This application claims the benefit under 35 U.S.C. 119(e) of U.S. Provisional Patent Application Ser. No. 60/538,834 filed Jan. 23, 2004.

### BACKGROUND OF THE INVENTION

1. Field of the Invention

The present invention relates generally to apparatus for controlling the positioning of solar panels which may be arranged independently or in groups or arrays. More particularly, the present invention relates to positioning apparatus for controlling the orientation of a solar panel(s) of the type normally mounted on motor homes, trailers and the like with the positioning system being controllable from a remote location, either inside or outside of the vehicle.

2. Description of the Prior Art

It has become customary to mount a solar panel or an array of such panels on the rooftop of vehicles such as motor homes, trailers and the like. In the prior art, orientation of the solar panel, for the purpose of collecting solar rays, normally requires some type of manual manipulation, usually from a ladder or by actually climbing onto the vehicle roof. Such positioning systems are usually very rudimentary and often involve adjustable braces or the like connected between the solar panel and the vehicle roof. An example of such an arrangement is disclosed in U.S. Pat. No. 5,969,501 to Glidden et al. Alternatively hand crank operated panel lifting apparatus has been utilized to position motor vehicle roof-mounted solar panels. U.S. Pat. No. 5,379,753 to Noennich illustrates a device of this type. In the latter instance, crank elements are mounted so as to extend through the roof of the vehicle, allowing a person within the vehicle to operate a hand crank so as to position the solar panel. This arrangement, of course, requires openings to be made in the vehicle roof as an after market installation which may result in leakage problems or other structural damage to the motor vehicle or trailer. A need thus arises for a remotely controllable power unit and mounting operable either from within or without the vehicle to position solar panels. The positioning apparatus must be compact and otherwise adaptable to the motor home or other vehicle roof structure and must be acceptable in appearance and compatibility with the vehicle structure.

### SUMMARY OF THE INVENTION

A single solar panel or more commonly an array of two or more solar panels may be mounted on the vehicle roof usually carried in a more or less flat generally horizontal non-use position on the roof surface. In order for the generally flat panels to be moved from the horizontal position and oriented to the in-use position at an angle to the roof surface, they are pivoted or hinged along one lateral edge relative to the roof surface of the vehicle. An elongated base structure is anchored to the vehicle roof surface adjacent to the lateral edge of the panel(s) which extends at right angles to the hinged edge. A mast structure is connected to a lift bar which is fixed to the lateral edge(s) of the panel(s) opposite the hinged edge(s) to form a lift structure to raise the panel(s) by pivoting about the hinged edge. One end of the base structure is connected to the mast by means of a swing arm or swing arms which extend between the mast structure and a pivot point adjacent to the end of the base structure which is in alignment with the pivotal axis of the panel edge. The swing arm or arms may be connected adjacent the top end of the mast or intermediate the top and bottom ends thereof. A motor driven extendable link or arm is pivoted at one end to the base structure intermediate the ends of the base. The opposite end of the extendable link is pivotally connected to the mast either above or below the pivotal connection of the swing arms. In the present illustrated embodiment, the extendable link is disclosed by way of example as a motor driven screw jack. It will be understood that the type of extendable link, the structural detail and the mode of operation may be chosen from any number of equivalent extendable link devices. With this arrangement, the extendable length power unit may be extended to cause the panel(s) to pivot about their axis to orient the panel(s) for catching solar rays. In the non-use position of the panel(s), only the mast remains upstanding and may be kept to an acceptable design height above the roof surface.

### BRIEF DESCRIPTION OF THE DRAWINGS

FIG. 1 is a perspective view of the panel positioning apparatus mounted on the roof of a motor vehicle;

FIG. 2 an exploded perspective view of the panel positioning mechanism;

FIG. 3 a side elevational view of the panel positioning system in the lowered non-use position;

FIG. 4 is a side elevational view of the panel and positioning system in the raised in-use position;

FIG. 5 is an exploded perspective view of an electrical limit switch unit carried on the extendable link;

FIG. 6 is an exploded partial perspective view of the pivotal mounting for the solar panel;

FIG. 7 is a side elevational view of an alternative embodiment of the panel positioning system; and

FIG. 8 is a perspective view of a protective cover for the panel positioning apparatus.

### DETAILED DESCRIPTION OF THE PREFERRED EMBODIMENTS

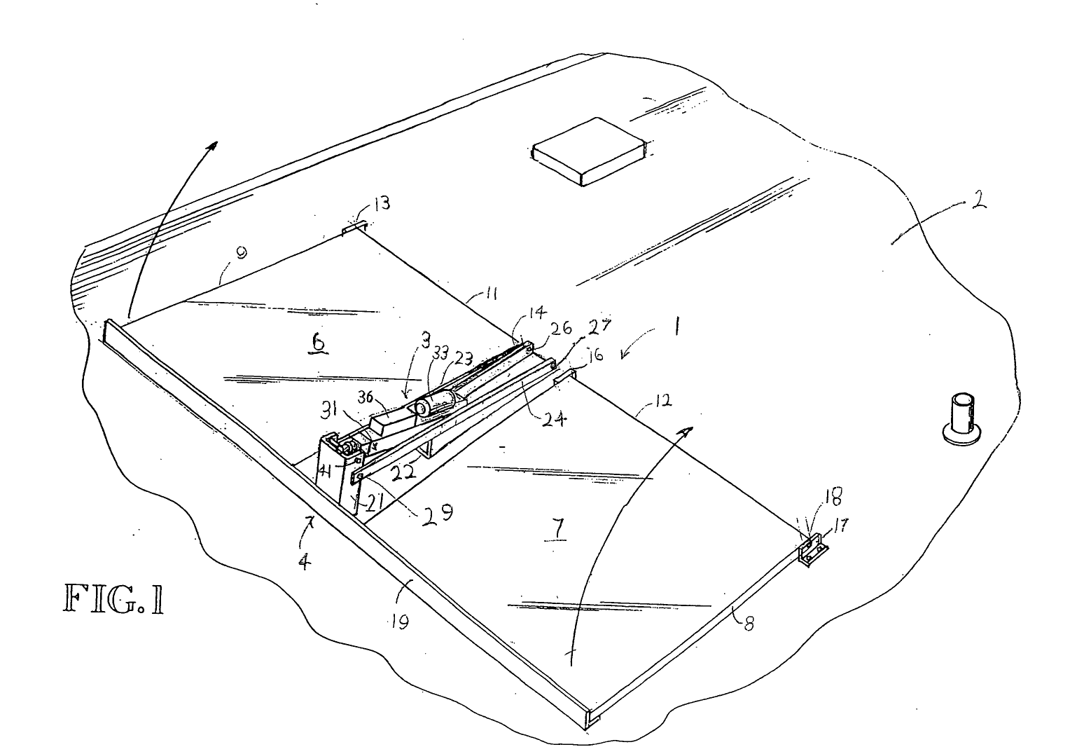

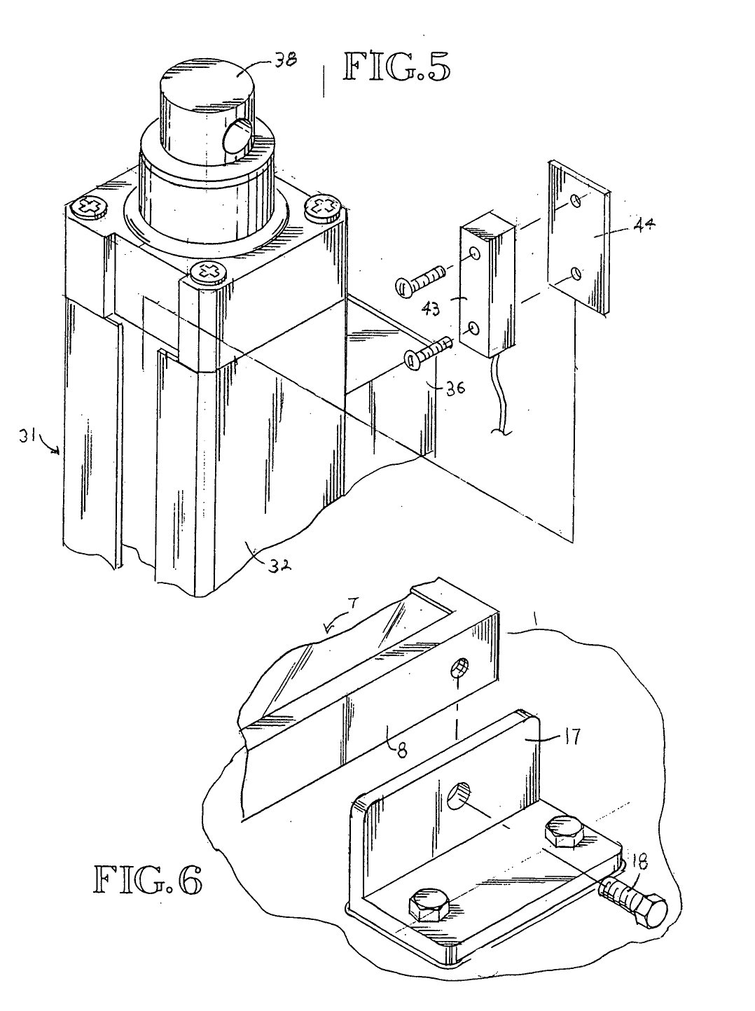

Referring to FIG. 1, the solar panel and positioning system 1 is illustrated as being mounted on the roof 2 of a motor vehicle such as a motor home, trailer or the like. The positioning system includes extendable link lift structure 3, lift bar and mast 4, and solar panels 6 and 7. It will be understood that the solar panels 6 and 7 are conventional staples of commerce designed for converting solar energy into electrical energy. In FIG. 1, the particular solar panels illustrated are generally flat and rectangular in configuration. The panels comprise solar cells located in a central area surrounded by rectangular support frames 8 and 9 respectively, giving the panel dimensional stability. As illustrated in FIG. 1, the solar panels are mounted for rotation about respective lateral edges 11 and 12 by means of pivot brackets 13-14 and 16-17 respectively. The solar panels are mounted for rotation about a common axis along aligned lateral edges 11 and 12 respectively by means such as bolts or studs 18. Their relationship is shown in detail in FIG. 6. The solar panels 6 and 7 are illustrated in their non-use position in FIG. 1 and will be raised to the in-use position in the direction of the arrows in FIG. 1 as they are rotated about the axis provided by the pivot bolts 18.

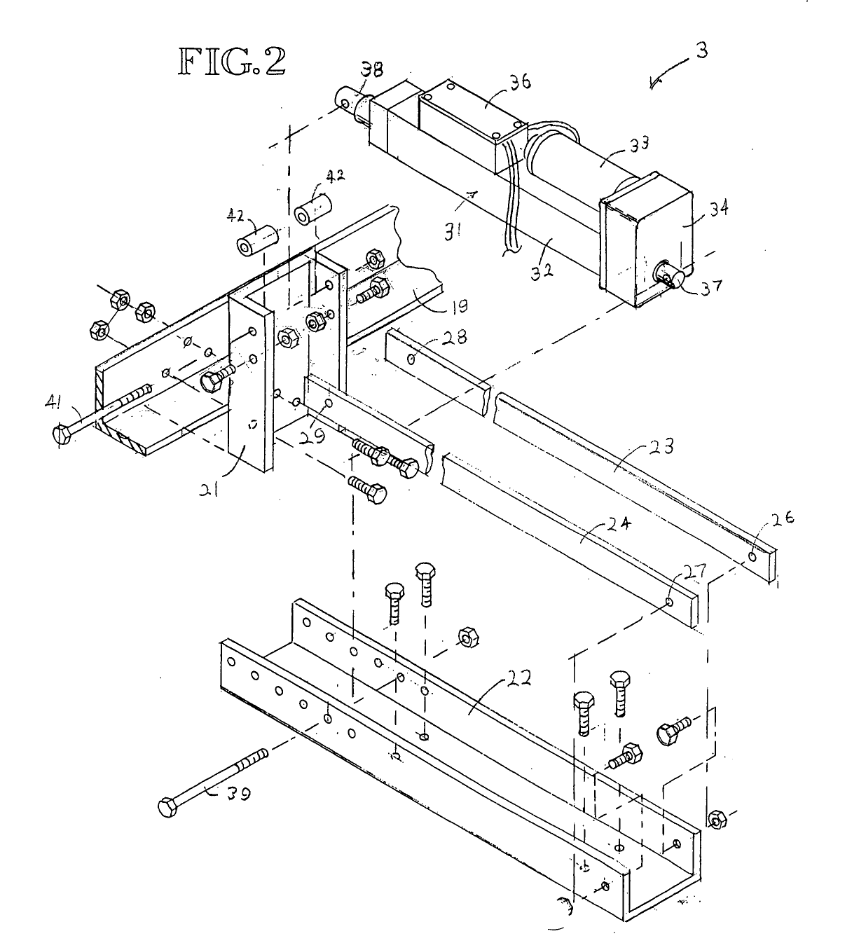

In the present illustrated embodiments, the panels 6 and 7 may be joined together by the elongated angle lift bar 19 which may be constructed from lightweight material such as aluminum. The lift bar 19 is securely fastened to the lateral edges of the panels 6 and 7 opposite the pivoted lateral edges 11 and 12 as shown in FIG. 1. While two such solar panels 6 and 7 are illustrated in the present embodiment, it will be understood that the present panel positioning apparatus may also be applied to a single panel or an array of panels in excess of the two shown. The lift bar 19 is provided with an upstanding U-shaped mast 21 located in the central portion of the lift bar between the solar panels 6 and 7. The mast 21 may be bolted or otherwise securely and rigidly mounted to the lift bar 19 as shown in detail in FIG. 2.

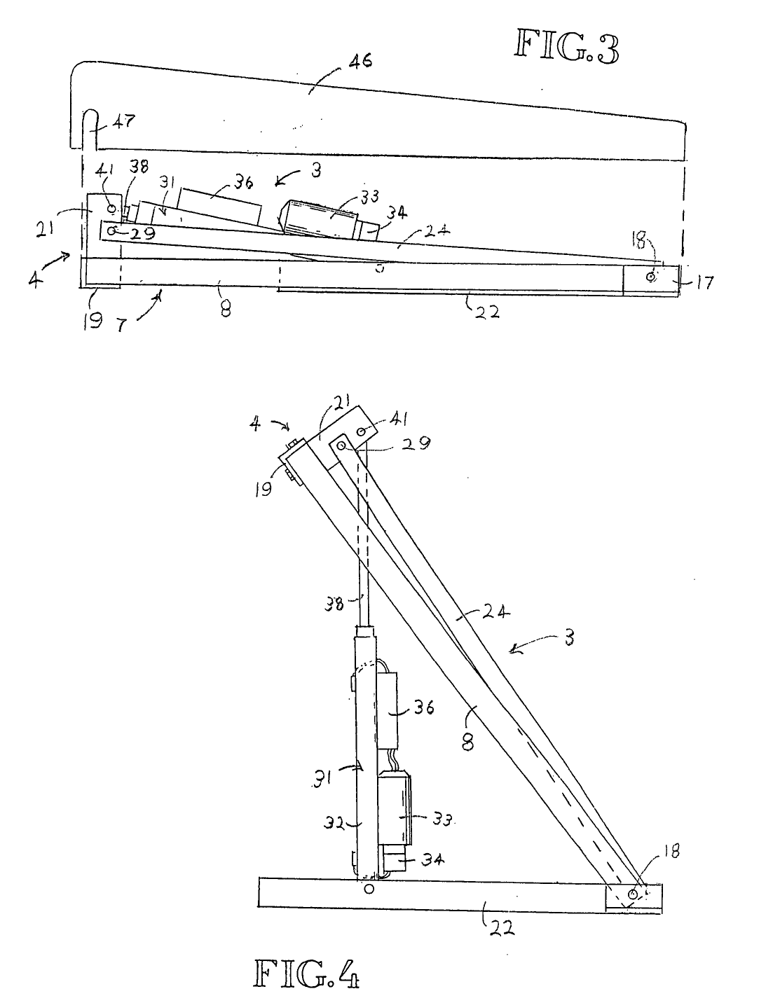

Power lift structure and linkage 3 comprises a U-shaped channel base 22 which may be constructed from aluminum channel stock or the like and is securely attached to the surface of roof 2 of the vehicle by bolting or the like as shown in detail in FIG. 2. The channel 22 as seen in FIG. 1 is located between the two solar panels 6-7 and parallel to the edges thereof with one end extending to the pivoted edges 11 and 12 of the solar panels. The base is connected to the mast 21 by means of one or more swing arms or links 23-24. The links 23 and 24 are pivotally connected to the sides of the U-shaped channel 22 as at 26 and 27 respectively as shown in detail in FIG. 2. The opposite ends of the links 23 and 24 are pivoted to the mast 21 as at the points 28 and 29 respectively. It is to be noted that the pivotal axis provided by the pivot points 26 and 27 are aligned and coincident with the pivotal axis of the solar panels provided by the bolts 18. In this manner, the relationship between the solar panels and the swing arms 23 and 24 remains constant as illustrated in FIGS. 3 and 4 as the solar panels are raised from the horizontal to an in-use position.

The lifting action of the power lift structure 3 in the present embodiment is provided by an extendable link in the nature of a screw jack assembly 31 shown in detail in FIGS. 2 and 5. The screw jack may be a commercially available unit such as that manufactured by the Duff Nortan Company of Charlotte, N.C. The screw jack structure is well known in the art and usually includes an elongated housing 32, an electric motor 33, a gearing unit 34 connecting the motor drive to the screw element and an electrical switching unit 36 for controlling the operation of the extendable link. Referring to FIGS. 2-4, the housing 32 will be provided with a stationary projecting connector element 37 fixed to the housing for the purpose of pivotally connecting the housing to a base. An extendable screw member within the housing (not shown) is connected to an extendable nonrotatable ram 38. FIGS. 2 and 3 illustrate the ram 38 in the withdrawn position and FIG. 4 illustrates the ram 38 in the extended position which provides the extendable link for the lift structure. As illustrated in FIG. 2 the stationary connector 37 of the screw jack is pivoted to the base structure 22 by means of a pivot bolt or the like 39 which extends through a bore in the connector 37 allowing the entire screw jack assembly to be pivoted relative to the base 22 during lifting. The distal end of the ram 38 is connected to the mast 21 by means of the pivot bolt 41 which passes through a suitable bore in the end of the ram 38 and is held in the centered position by the spacers 42. Similar spacers (not shown) may also be used on the pivot bolt 39 to center the connector 37 between the sides of base 22. In this manner the screw jack extendable link may be operated to move the solar panels 6 and 7 from the horizontal non-use position of FIG. 3 to the in-use position shown in FIG. 4 as the screw jack extends, the solar panels and the swing arms 23 and 24 rotate about the pivotal axis provided by the pivot bolts 18 and the pivots 26 and 27. It is contemplated that the switching unit 36 may be controlled from a remote location either inside or outside of the vehicle through suitable electrical leads and a power source. The retracted and extended positions of the ram 38 may be suitably controlled by limit switches (not shown) located within the screw jack assembly and actuated by position detectors or the like such as that shown at 43 in FIG. 5 mounted at selected locations along the length of the housing 32. The detector 43 may be mounted on a guide plate or the like 44 received in a suitable slotting arrangement on the surface of the housing 32 as shown in FIG. 5. The position limiting switches are normally a part of the commercially available screw jack unit. It will be understood that other means of limiting the extended and retracted positions of the screw jack assembly may also be utilized without departing from the spirit and scope of the invention.

Since the power lift structure and linkage is located at an exposed outside location on the vehicle roof surface, it may be desirable to provide a suitable cover or hood to protect the apparatus from the elements. Such a cover is illustrated in FIGS. 3 and 8. The hood may be constructed from metal or molded plastic material and will be designed to cover the mast structure, the base member 22, the power lift and linkage 3, as well as the various pivotal connections. The cover will be provided with waterproof side and top walls and may be fitted over the lift structure and held in place by such means a pressure or snap fit, clips, bolts or the like. In any event, the protective cover preferably contacts the roof surface with suitable slots 47 and 48 being formed in the opposite forward side walls to accommodate the upstanding flange of the lift bar 19 as illustrated in FIG. 3.

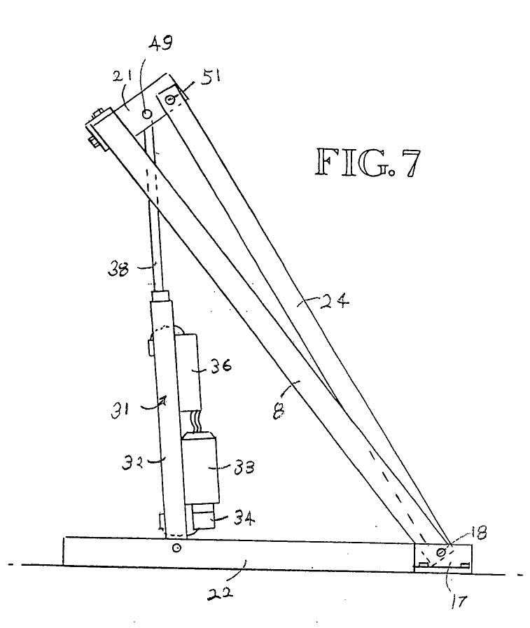

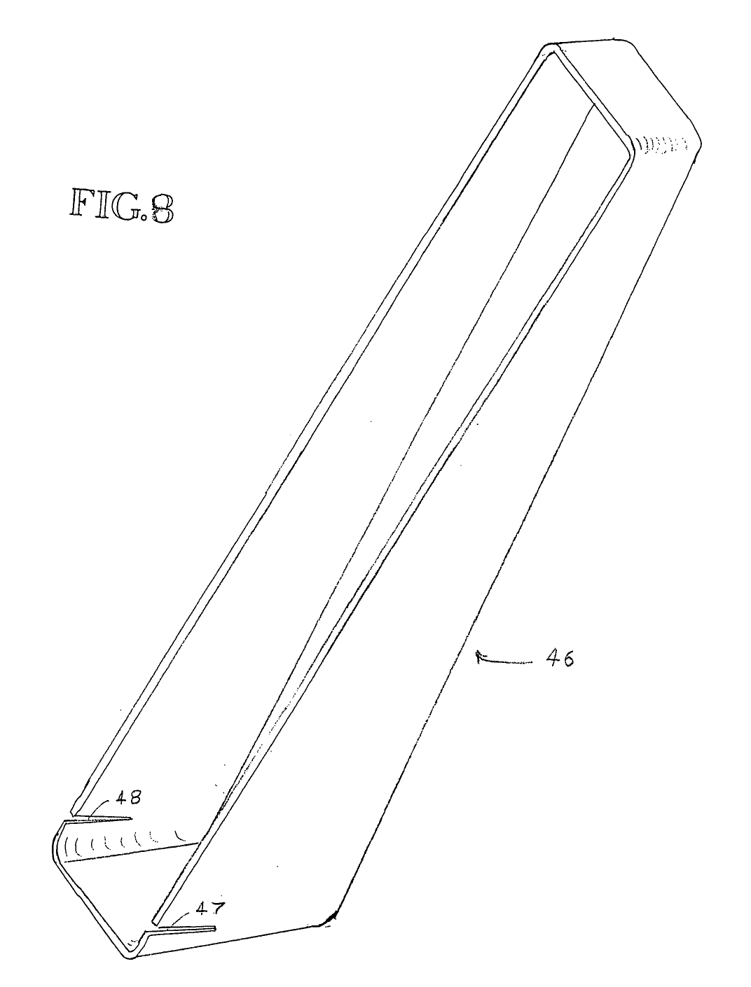

While the embodiment shown in FIGS. 1-4 utilizes a configuration wherein the pivotal connection between the ram 38 of the screw jack and the mast 21 is located above the pivotal connections 28 and 29, in some instances it may be preferable to modify this arrangement. FIG. 7 illustrates a modification of the pivotal arrangement wherein the ram 38 is connected to the mast 21 at a pivot point 49, roughly comparable to the position of the pivot points 28 and 29 of the FIGS. 1-4 embodiment. Links 23 and 24 of this embodiment are connected above the pivot point 49, the pivot point for link 24 being shown at 51 in FIG. 7. The position of pivot point 51 roughly corresponds to the position of pivot point 41 of the ram 38 in the FIGS. 1-4 embodiment. Utilization of the FIG. 7 embodiment wherein the positions of the pivotal connections of the ram 38 and the links 23 and 24 are reversed, may be an advantage in those instances where it is desired to decrease the leverage of the mast 21 against the lift bar 19 to thereby decrease the pressure tending to twist the lift bar. These considerations may be of concern depending on the length of the mast 21.

Although the present invention has been described with reference to the preferred embodiments, it will be apparent that alternative structural or mechanical details may be employed in order to accomplish the objects of the invention. As an example, different types of extendable link assemblies may be utilized such as pneumatic or hydraulic rams with various arrangements of limit switches and the like for limiting the movement of the solar panels. Various configurations of protective covers may be utilized and various materials of construction employed for the various linkages and pivotal connections. Still other modifications of remote control and electrical power sources for the extendable link may be utilized to raise and lower the solar panels from remote locations.

1. Positioning apparatus for a support surface mounted solar energy system, comprising;
a lift structure attached to at least one pivotal axis mounted solar panel and including a mast spaced from the solar panel pivotal axis and extending away from the support surface,
a base structure mounted on the support surface,
at least one swing link connected at one end thereof to said mast and the opposite end in pivotal relation to the base, and
an extensible link pivotally connected between the mast and an intermediate point on the base.

2. Positioning apparatus for a support surface mounted solar energy system, comprising;
a lift bar attached to an edge of at least one solar panel, said panel having an opposite edge pivoted to the support surface,
a mast connected to the lift bar,
a base mounted on the support surface,
at least one swing link having one end connected to the mast and the opposite end pivotally connected to the base, said swing link and opposite edge of the solar panel being pivoted about a common pivotal axis, and
an extensible link pivotally connected between the mast and an intermediate point on the base for moving said at least one solar panel toward and away from the support surface.

3. Positioning apparatus for a solar energy system mounted on a mobile support surface in generally parallel relation thereto, comprising;
a lift bar attached to a first lateral edge of at least one generally planar solar panel,
said at least one solar panel having a second opposite parallel lateral edge mounted on a first pivotal axis for orientation of said panel at an angle to the support surface,
a mast connected to the lift bar and extending away from the support surface,
a base structure mounted on the support surface adjacent said at least one solar panel,
at least one swing link having a pivotal connection at one end to the base structure for movement about a second pivotal axis in alignment with said first pivotal axis, the opposite end thereof being connected to the mast, and
an extensible link pivotally connected at one end to the base structure at a point spaced from said swing link pivotal connection and to the mast at the opposite end thereof,
whereby, upon extension of the extensible link, the lift bar is moved away from the support surface and said at least one solar panel is moved about said first pivotal axis to a position at an angle to the support surface.

4. The apparatus of claim 3 including:
pivot bracket means fixed to the support surface,
the opposite lateral edge of said at least one solar panel being connected to said bracket means defining said first pivotal axis.

5. The apparatus of claim 4 wherein the base structure is fixed to the support surface and includes a terminal end portion with means comprising said second pivotal axis,
the base structure extending along an edge of said at least one solar panel at right angles to said first and second lateral edges.

6. The apparatus of claim 5 including a plurality of said solar panels;
said solar panels being spaced along the length of the lift bar, and
said apparatus further including a plurality of said swing links with each swing link being connected to the mast and pivoted about an axis in alignment with said first and second axes.

7. The apparatus of claim 6 wherein the mast has a terminal end portion spaced from the lift bar,
each said swing links being connected to the mast adjacent said terminal end, and
said extensible link being pivotally connected to the mast at a point between the swing link connection point and the lift bar.

8. The apparatus of claim 6 wherein said mast has a terminal end portion spaced from said lift bar,
said extensible link being pivotally connected to the mast adjacent said terminal end, and
each said swing link being connected to the mast at a point between the extensible link connection and the lift bar.

9. The apparatus of claim 3 wherein the support surface comprises the roof section of a mobile vehicle;
said extensible link comprising a motor powered unit, and
remote control means for selectively actuating said motor powered unit to control the orientation of said at least one solar panel relative to the roof section.

10. The apparatus of claim 6 wherein the support surface comprises the roof section of a mobile vehicle,
said extensible link comprising a motor powered unit, and
remote control means for selectively actuating said motor powered unit to control the orientation of said solar panels relative to the roof section.
